(19) United States
(12) Patent Application Publication
(10) Pub. No.: US 2025/0208761 A1
(43) Pub. Date: Jun. 26, 2025

(54) MRAM

(71) Applicant: AISIN CORPORATION, Kariya (JP)

(72) Inventors: Hirokatsu TANAKA, Kariya-shi (JP); Takanobu NARUSE, Kariya-shi (JP)

(73) Assignee: AISIN CORPORATION, Kariya (JP)

(21) Appl. No.: 18/813,522

(22) Filed: Aug. 23, 2024

(30) Foreign Application Priority Data
Dec. 22, 2023 (JP) 2023-216550

(51) Int. Cl. G06F 3/06

(52) U.S. Cl. CPC G06F 3/0616; G06F 3/0659; G06F 3/0679

(57) ABSTRACT

An MRAM is configured such that the MRAM has a work area and a boot area, and the work area has a reliability determination area, and when data is written to the work area, the data is written to an area in the work area other than the reliability determination area, and new data that is different from old data stored in the reliability determination area is written to the reliability determination area, and data stored in the reliability determination area is read, and when the read data is different from the new data, the work area and another area are switched with each other.

### CROSS REFERENCE TO RELATED APPLICATIONS

This application is based on and claims priority under 35 U.S.C. § 119 to Japanese Patent Application No. 2023-216550, filed on Dec. 22, 2023, the entire content of which is incorporated herein by reference.

### TECHNICAL FIELD

This disclosure relates to an MRAM.

### BACKGROUND DISCUSSION

Conventionally, there is known a technique in which the remaining lifespan of an MRAM is computed based on statistical information, and when the MRAM reaches the lifespan, writing to the MRAM is prohibited (e.g., JP 2014-167809 A).

In the conventional technique, when an MRAM is close to its lifespan, writing to the MRAM cannot be performed.

This disclosure is made in view of the above-described problem, and an object of this disclosure is to provide a technique for extending the lifespan of an MRAM.

A need thus exists for an MRAM which is not susceptible to the drawback mentioned above.

### SUMMARY

An MRAM is configured such that the MRAM has a work area and a boot area, and the work area has a reliability determination area, and when data is written to the work area, the data is written to an area in the work area other than the reliability determination area, and new data that is different from old data stored in the reliability determination area is written to the reliability determination area, and data stored in the reliability determination area is read, and when the read data is different from the new data, the work area and another area are switched with each other.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a block diagram showing a configuration of an IC chip;

FIG. 2 is a flowchart of a lifespan management process;

FIG. 3 is a block diagram showing a configuration of the IC chip after switching a work area and a boot area with each other;

FIG. 4 is a block diagram showing a configuration of an IC chip; and

FIG. 5 is a block diagram showing a configuration of the IC chip after switching a work area and an unused area with each other.

### DETAILED DESCRIPTION

Here, an embodiment of this disclosure will be described in the following order:

(1) Configuration of an IC chip;

(2) Lifespan management process; and

(3) Other embodiments, etc.

(1) Configuration of an IC chip:

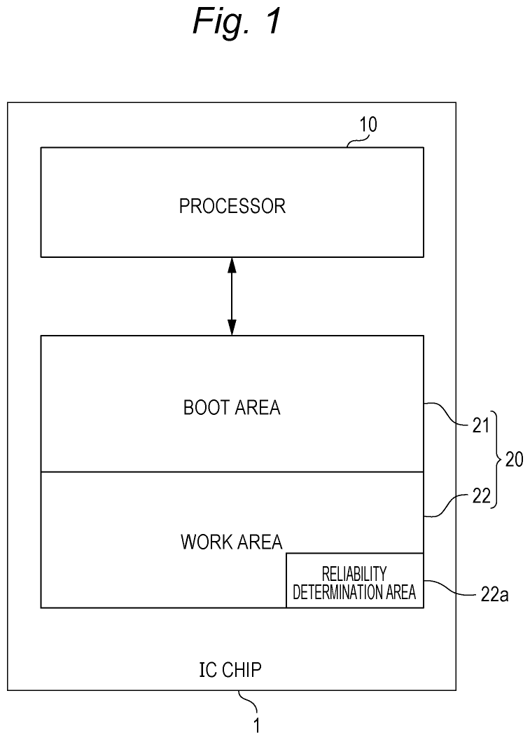

FIG. 1 is a block diagram showing a configuration of an IC chip 1 including a magnetoresistive random access memory (MRAM) 20 according to this disclosure. The IC chip 1 is a device that is provided as a package having various circuits formed therein, and is mounted on a general-purpose computer or a computer included in an in-vehicle device, etc. The IC chip 1 includes a processor 10 and the MRAM 20. The processor 10 implements various functions by executing a program recoded in the MRAM 20. The processor 10 can be implemented by publicly known various circuits and may include, for example, a storage device such as a static random access memory (SRAM).

The MRAM 20 is separated into areas in advance. Namely, the MRAM 20 has a boot area 21 and a work area 22. In the present embodiment, the boot area 21 is a storage area for an operating system. In the present embodiment, when supply of power to the IC chip 1 starts, the processor 10 reads the operating system stored in the boot area 21, by which a boot sequence is executed. When the boot sequence is completed, the processor 10 performs various processes under the execution of the operating system. Note that processes performed by the operating system also include a process performed by an application program that is executed under the execution of the operating system.

The work area 22 is a storage area for data that is handled in processes performed by the operating system. Namely, upon storing data during various processes performed under the execution of the operating system, the data is written to the work area 22.

Furthermore, in the present embodiment, the work area 22 includes a reliability determination area 22a. In the present embodiment, the reliability determination area 22a is an area having capacity for one bit. When data is written to the work area 22 by a process performed by the operating system, new data that is different from old data stored in the reliability determination area 22a is written to the reliability determination area 22a.

Specifically, when given data is written to an area in the work area 22 other than the reliability determination area 22a, the reliability determination area 22a is rewritten. Namely, when old data stored in the reliability determination area 22a is “0”, new data “1” is written to the reliability determination area 22a. When old data stored in the reliability determination area 22a is “1”, new data “0” is written to the reliability determination area 22a.

When rewriting such as that described above is performed, every time given data is written to the work area 22, data in the reliability determination area 22a is rewritten. Hence, the number of rewrites performed in the reliability determination area 22a is greater than or equal to the number of rewrites performed in a given area in the work area 22. Thus, the number of rewrites performed in the reliability determination area 22a has a maximum value of the number of rewrites performed in the work area 22.

Therefore, the reliability determination area 22a is the fastest to reach its lifespan in the work area 22. Hence, when the reliability determination area 22a has reached its lifespan, the work area 22 is switched with another area that has not reached its lifespan, by which the lifespan of the work area 22 can be extended.

Hence, in the present embodiment, after writing new data to the reliability determination area 22a, data is read, and when the read data is different from the new data, the work area 22 and another area are switched with each other.

Note that, in the present embodiment, another area is the boot area 21. Namely, writing to the boot area 21 is performed upon writing the operating system, but in many cases, writing is not performed or not performed almost at all thereafter. Thus, normally, the number of writes performed in the boot area 21 is significantly small compared to the number of writes performed in the work area 22. Even if rewriting, modifications, etc., are performed on the operating system, normally, the number of writes performed in the boot area 21 is smaller than the number of writes performed in the work area 22.

Thus, by switching the work area 22 and the boot area 21 with each other when data read from the reliability determination area 22a is different from written data, the effective usable period of the MRAM 20 can be extended.

(2) Lifespan management process:

Next, a lifespan management process performed in the IC chip 1 will be described. When supply of power to the IC chip 1 starts, the processor 10 reads an operating system by referring to the boot area 21 (step S100). Namely, data of the operating system stored in the boot area 21 is loaded into a memory in the processor 10 to start execution of the operating system. In this state, the processor 10 can perform any process executable under the execution of the operating system.

The processor 10 performs a given process at given timing under the execution of the operating system (step S105). When the given process is performed, the processor 10 determines whether or not data is to be written to the work area 22 by the process (step S110). If it is not determined at step S110 that data is to be written to the work area 22, then the processor 10 repeats processes at and after step S105.

If it is determined at step S110 that data is to be written to the work area 22, then the processor 10 rewrites the reliability determination area 22a (step S115). Namely, old data stored in the reliability determination area 22a is overwritten with new data. In addition, the processor 10 writes data to the work area 22 (step S120). Namely, data to be written as a result of the process performed at step S105 is written to an area in the work area 22 other than the reliability determination area 22a.

Then, the processor 10 reads data in the reliability determination area 22a (step S125) and determines whether or not the data is normal (step S130). Namely, when the read data matches the data having been rewritten at step S115, it is determined that the data is normal. When those pieces of data do not match each other, it is not determined that the data is normal.

If it is determined at step S130 that the data is normal, then the processor 10 repeats processes at and after step S105. If it is not determined at step S130 that the data is normal, then the processor 10 switches the work area 22 and the boot area 21 with each other (step S135). Namely, the processor 10 transfers the data of the operating system stored in the boot area 21 to an area in the work area 22 other than the reliability determination area 22a. Note that the switching may be performed by various techniques, and the transfer may be performed while the data is saved in a free area in the MRAM 20, a backup area in a memory external to the MRAM 20, etc.

Then, the processor 10 performs processes at and after step S100, i.e., the processor 10 performs the processes again, starting with reading of the operating system. Namely, the IC chip 1 reboots. Note, however, that after the rebooting, an area having served as the boot area 21 before the rebooting is used as the work area 22, and an area having served as the work area 22 before the rebooting is used as the boot area 21. Note that the rebooting may be omitted if it is possible to suspend the process performed at step S105, and switch data in the boot area 21 and data in the work area 22 with each other while those pieces of data in the boot area 21 and the work area 22 are saved in other areas, etc., and then resume the process performed at step S105 after completing the switching.

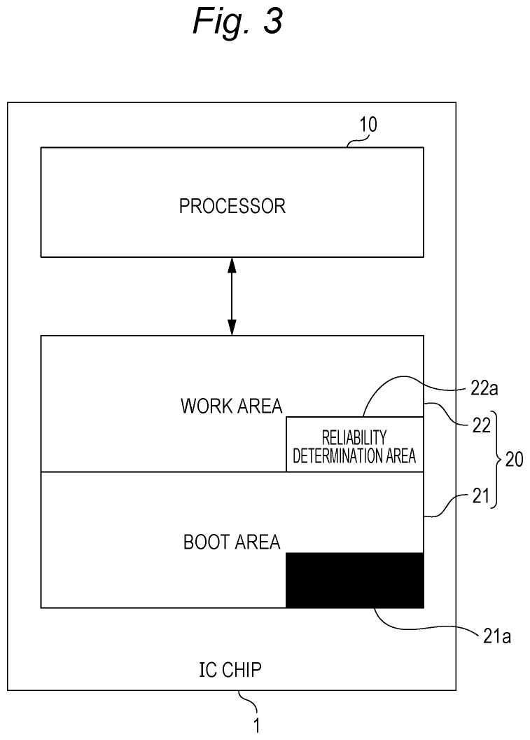

FIG. 3 shows a state after performing switching on the MRAM 20 shown in FIG. 1. Since an area having served as the boot area 21 before the rebooting serves as the work area 22, a part of the area is used as the reliability determination area 22a. In addition, an area having served as the work area 22 before the rebooting serves as the boot area 21. Note, however, that an area 21a having been used as the reliability determination area 22a before the rebooting has reached its lifespan for the number of rewrites, and thus, is excluded from the boot area 21 and is not used.

According to the above-described configuration, after using the work area 22 until reaching the lifespan of the reliability determination area 22a, the work area 22 can be further used until reaching the lifespan of another reliability determination area 22a. As a result, compared to a case in which switching is not performed, the lifespan of the MRAM 20 can be extended to about twice the original lifespan.

(3) Other embodiments, etc.:

The above-described embodiment is an example for implementing this disclosure, and various other embodiments can also be adopted. For example, an MRAM may have various usage modes, and instead of forming an MRAM on a chip together with a circuit for implementing functions other than those of the MRAM, e.g., a processor, an MRAM may be formed as a chip including only the MRAM. In addition, a chip including an MRAM may include a circuit other than a processor.

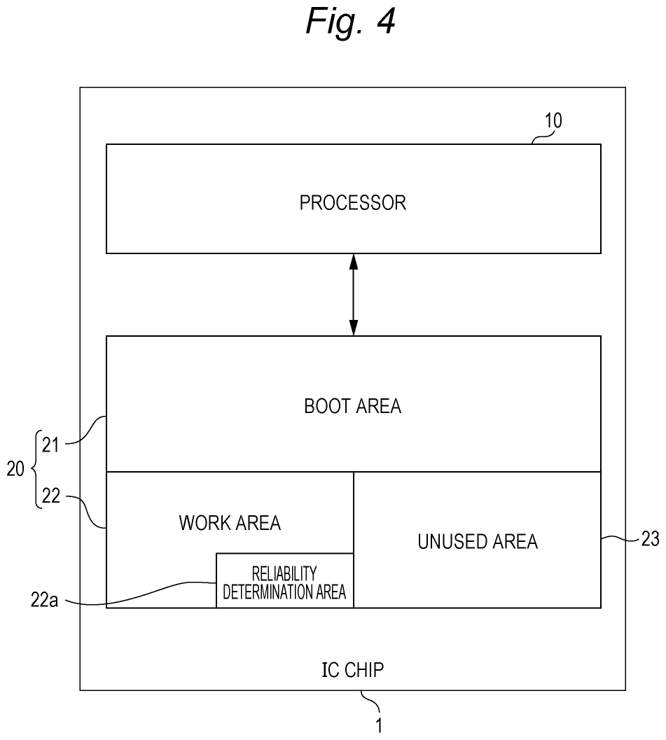

In addition, an area with which a work area is switched is not limited to a boot area. For example, a configuration may be adopted in which a work area and an unused area included in an MRAM are switched with each other. FIG. 4 is a block diagram showing a configuration in which after manufacturing an IC chip 1, an unused area 23 is reserved in addition to a boot area 21 and a work area 22. In an example shown in FIG. 4, the unused area 23 having equivalent capacity to the work area 22 is reserved in advance.

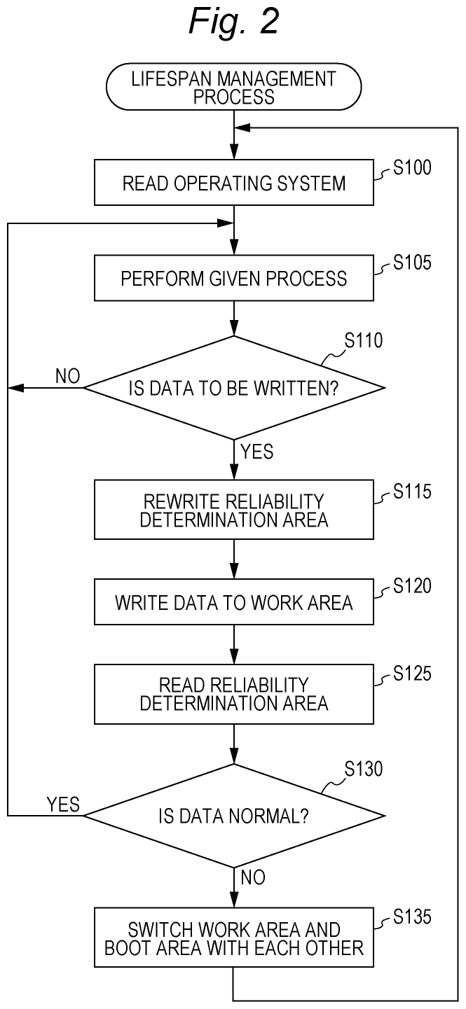

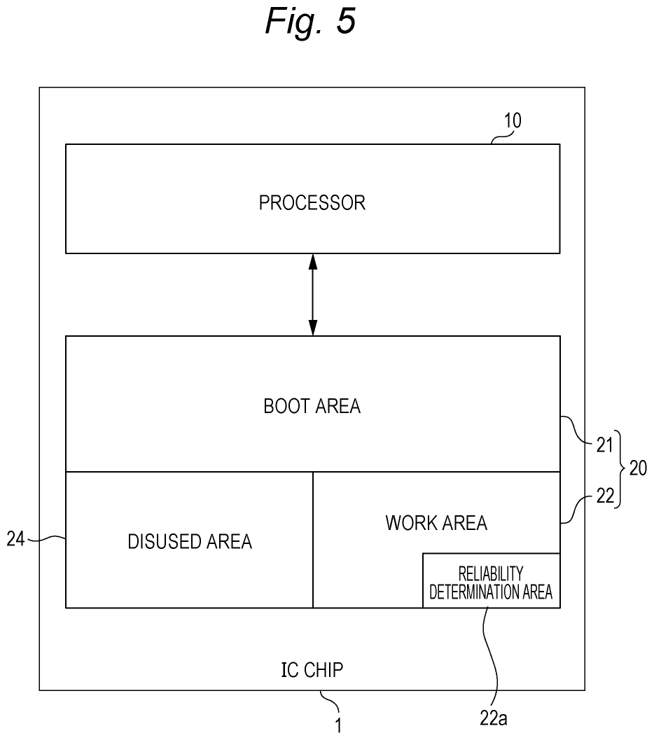

In this configuration, too, the lifespan of the MRAM is managed by the process shown in FIG. 2. Note, however, that at step S135, the work area 22 and the unused area 23 are switched with each other. Specifically, at step S135, the processor 10 transfers data stored in the work area 22 other than data in the reliability determination area 22a to the unused area 23. When the transfer is done, as shown in FIG. 5, an area having served as the unused area 23 serves as the work area 22. In addition, the processor 10 reserves a reliability determination area 22a in the new work area 22. Furthermore, an area having served as the work area 22 before the transfer serves as an disused area 24. The processor 10 does not use the disused area 24 thereafter.

According to the above-described configuration, after using the work area 22 until reaching the lifespan of the reliability determination area 22a, the work area 22 can be further used until reaching the lifespan of another reliability determination area 22a. As a result, compared to a case in which switching is not performed, the lifespan of the MRAM 20 can be extended to about twice the original lifespan. In addition, since the boot area 21 is not switched, even if an area having used as the work area 22 before switching has reached its lifespan, data in the boot area 21 is not affected.

An MRAM is a magnetic random access memory and may be any memory that stores information by changes in a magnetization state. Namely, the MRAM has characteristics that compared to other publicly known memories, a period during which data is guaranteed to be held is relatively long, but the number of times rewriting of data is guaranteed is relatively small. As such, even if the MRAM has a characteristic that the number of times rewriting is guaranteed is relatively small, by switching a work area, it is possible to extend the lifespan of the MRAM.

A boot area is an area used upon booting, and thus, is used, for example, upon boot-up of a system that uses an MRAM, but after the boot-up, the boot area is not frequently accessed. On the other hand, a work area is an area used after the boot-up and is often accessed compared to the boot area.

A reliability determination area may be any area whose data is rewritten every time data is written to a work area. Namely, every time data is written to the work area, new data that is different from old data stored in the reliability determination area is written to the reliability determination area. Note that in the above-described embodiment, the reliability determination area is an area reserved in the work area, but the reliability determination area may be reserved in an area other than the work area. In this case, upon switching the work area and another area with each other, a reliability determination area is newly reserved in an unused area.

When data is written to the work area, new data that is different from old data stored in the reliability determination area is written to the reliability determination area. Namely, the old data stored in the reliability determination area is overwritten with different new data. By performing such rewriting, the number of rewrites performed in the reliability determination area can be greater than or equal to a maximum value of the number of rewrites performed in the work area.

The old data and the new data may be any data as long as they are different from each other. As in the above-described embodiment, if the reliability determination area has one bit, then either one of the old data and the new data is 1 and the other is 0. The reliability determination area may have multiple bits. In this case, it is desirable that upon rewriting the reliability determination area, all bits be rewritten with different data.

Furthermore, a technique of this disclosure is also applicable as a program or a method. In addition, a system, a program, and a method such as those described above may be implemented as a single device or may be implemented as a plurality of devices, and thus include various modes. In addition, changes can be made as appropriate, e.g., a part is software and a part is hardware. Furthermore, the disclosure is also feasible as a recording medium for a program that controls the system. Needless to say, the recording medium for a program may be a magnetic recording medium or may be a semiconductor memory, and any recording medium to be developed in the future can also be considered exactly in the same manner.

An MRAM is configured such that the MRAM has a work area and a boot area, and the work area has a reliability determination area, and when data is written to the work area, the data is written to an area in the work area other than the reliability determination area, and new data that is different from old data stored in the reliability determination area is written to the reliability determination area, and data stored in the reliability determination area is read, and when the read data is different from the new data, the work area and another area are switched with each other.

According to the above-described configuration, in the MRAM, upon writing given data to the work area, data stored in the reliability determination area is rewritten. Hence, when a given area in the work area is compared with the reliability determination area, the reliability determination area has the highest frequency of use and thus is the fastest to reach its lifespan. A determination as to whether or not the lifespan has been reached can be made by reading data stored in the reliability determination area and determining whether or not the read data matches written data. Hence, by switching the work area with another area when the reliability determination area has reached its lifespan, it becomes possible to further use the work area for a long period of time. As a result, the lifespan of the MRAM can be extended.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. An MRAM having a work area and a boot area, the MRAM comprising:
a reliability determination area,
wherein
when data is written to the work area, new data that is different from old data stored in the reliability determination area is written to the reliability determination area, and
data stored in the reliability determination area is read, and when the read data is different from the new data, the work area and another area are switched with each other.

2. The MRAM according to claim 1, wherein the another area is the boot area.

3. The MRAM according to claim 1, wherein the another area is an unused area included in the MRAM.

4. The MRAM according to claim 1, wherein
the boot area is an area for storing an operating system, and
the work area is an area for storing data that is handled in a process performed by the operating system.
